(19) United States
(12) Patent Application Publication
(10) Pub. No.: US 2012/0085393 A1
(43) Pub. Date: Apr. 12, 2012

(54) SOLAR CELL MODULE AND METHOD OF MANUFACTURING THE SAME

(75) Inventors: Young-Sang Cho, Yongin-si (KR); So-Young Lim, Hwaseong-si (KR); Tae-Hong Min, Gumi-si (KR)

(73) Assignee: SAMSUNG ELECTRONICS CO., LTD., Suwon-si (KR)

(21) Appl. No.: 13/154,696

(22) Filed: Jun. 7, 2011

(30) Foreign Application Priority Data
Oct. 11, 2010 (KR) 10-2010-0098910

(51) Int. Cl. H01L 31/05; H01L 31/048

(52) U.S. Cl. 136/251; 136/244

(57) ABSTRACT

A solar cell module includes a circuit board, a plurality of solar cells disposed on a first surface of the circuit board, a plurality of metal terminals formed on the first surface of the circuit board, and a plurality of wires electrically connecting the plurality of solar cells and the metal terminals. The circuit board has a second surface opposite to the first surface, the rear surface comprising openings corresponding to the metal terminals, the openings exposing the metal terminals to an exterior of the solar cell module, thus forming contact terminals for the solar cell module.

### CROSS-REFERENCE TO RELATED APPLICATION

This application claims priority from Korean Patent Application No. 10-2010-0098910 filed on Oct. 11, 2010 in the Korean Intellectual Property Office, and all the benefits accruing therefrom, under 35 U.S.C. 119, the contents of which in its entirety are herein incorporated by reference.

### BACKGROUND OF THE INVENTION

1. Field of the Invention

The present inventive concept relates to a solar cell module, and more particularly, to a solar cell module that uses a flip-chip approach and has a reduced thickness.

2. Description of the Related Art

A solar cell is a device which converts energy of light into electrical energy. In a solar cell, light that is incident on a semiconductor material creates an electron-hole pair (EHP) within the semiconductor material. An electric field produced at a pn junction causes electrons to move to an n-type semiconductor and holes to move to a p-type semiconductor, thereby generating electrical current and, therefore, power. An assembly of multiple solar cells is commonly referred to as a solar module. Solar modules are commonly used to capture light energy from sunlight and to convert the captured light energy to electrical energy. Solar modules are commonly referred to as solar panels.

Recently, research has been conducted on a compact, thin, lightweight, and high-power solar cell module that can be used as an auxiliary power supply for portable information devices such as mobile phones or personal digital assistants (PDAs).

### SUMMARY

The present inventive concept provides a solar cell module having a reduced thickness, which can be manufactured by changing the structure or material of a PCB substrate in the solar cell module.

The present inventive concept also provides a solar cell module having a reduced thickness while having external contact terminals.

These and other features of the present inventive concept will be described in or be apparent from the following description of the preferred embodiments.

According to an aspect of the present inventive concept, there is provided a solar cell module including a circuit board, a plurality of solar cells disposed on a first surface of the circuit board, a plurality of metal terminals formed on the first surface of the circuit board, and a plurality of wires electrically connecting the plurality of solar cells and the metal terminals. The circuit board has a second surface opposite to the first surface, the second surface comprising openings corresponding to the metal terminals, the openings exposing the metal terminals to an exterior of the solar cell module, thus forming contact terminals for the solar cell module.

In some exemplary embodiments, the wires comprise at least one of copper, nickel, gold and silver.

In some exemplary embodiments, the plurality of solar cells is connected to each other by the wires.

In some exemplary embodiments, an adhesive layer is interposed between the plurality of solar cells and the circuit board.

In some exemplary embodiments, the solar cell module further comprises a transparent resin at least partially surrounding the plurality of solar cells.

In some exemplary embodiments, the transparent resin comprises at least one of underfill resin and ethylene vinyl acetate (EVA).

In some exemplary embodiments, the solar cell module further comprises a transparent panel disposed on the transparent resin.

In some exemplary embodiments, the metal terminals are formed at opposite ends of the circuit board.

According to another aspect of the present inventive concept, there is provided a solar circuit module including a metal circuit board, a plurality of solar cells disposed on a first surface of the metal circuit board, a plurality of wires electrically connecting the plurality of solar cells and the metal circuit board, and a transparent resin at least partially surrounding the first surface of the metal circuit board and a second surface of the metal circuit board opposite the first surface of the metal circuit board. The transparent resin comprises holes exposing portions of the metal circuit board to an exterior of the solar circuit module, thus forming contact terminals for the solar circuit module.

In some exemplary embodiments, the metal circuit board is divided into a plurality of regions.

In some exemplary embodiments, the metal circuit board comprises first and second regions extending lengthwise in parallel, and a third region at least partially surrounding the first and second regions.

In some exemplary embodiments, the plurality of solar cells is connected to each other by the wires.

In some exemplary embodiments, the wires comprise at least one of copper, nickel, gold and silver.

In some exemplary embodiments, the transparent resin comprises at least one of underfill resin and ethylene vinyl acetate (EVA).

In some exemplary embodiments, the solar circuit module further comprises a transparent panel disposed on the transparent resin.

According to another aspect of the inventive concept, there is provided an energy conversion module, comprising: a substrate having a first surface and a second surface opposing the first surface; a plurality of solar cells disposed on the first surface of the substrate; a plurality of metal terminals formed on the first surface of the substrate; a plurality of wires formed to electrically connect the plurality of solar cells and the metal terminals; a transparent resin at least partially surrounding the solar cells; and a transparent panel disposed on the transparent resin. The second surface of the substrate comprises a plurality of openings in correspondence with the metal terminals to expose the metal terminals to an exterior of the energy conversion module, thus forming contact terminals of the energy conversion module.

In some exemplary embodiments, the substrate is a circuit board.
In some exemplary embodiments, the module further comprises an adhesive layer between the plurality of solar cells and the circuit board.
In some exemplary embodiments, the energy conversion module is a solar cell module which converts light energy to electrical energy.
In some exemplary embodiments, the wires comprise at least one of copper, nickel, gold and silver.

According to another aspect of the present inventive concept, there is provided a method of manufacturing a solar cell module, the method including disposing a plurality of solar cells on one surface of a circuit board, forming metal terminals on the circuit board, providing wires electrically connecting the plurality of solar cells and the metal terminals, and forming holes on a rear surface of the circuit board at locations corresponding to the metal terminals, and forming contact terminals.

### BRIEF DESCRIPTION OF THE DRAWINGS

The foregoing and other features and advantages of the inventive concept will be apparent from the detailed description of preferred embodiments of the inventive concept contained herein, as illustrated in the accompanying drawings, in which like reference characters refer to the same parts or elements throughout the different views. The drawings are not necessarily to scale, emphasis instead being placed upon illustrating the principles of the inventive concept. In the drawings, the thickness of layers and regions may be exaggerated for clarity.

FIG. 1 is a schematic cross-sectional view of a conventional solar cell module.

FIG. 2 is a schematic cross-sectional view of a solar cell module according to an embodiment of the present inventive concept.

FIG. 3A is a schematic rear view of the solar cell module of FIG. 2.

FIG. 3B is a schematic plan view of the solar cell module of FIG. 2.

FIG. 4 is a flowchart of a method of manufacturing a solar cell module according to an embodiment of the present inventive concept.

FIGS. 5 through 8 are schematic cross-sectional views sequentially illustrating steps of a method of manufacturing a solar cell module according to an embodiment of the present inventive concept.

FIG. 9 is a schematic cross-sectional view of a solar cell module according to another embodiment of the present inventive concept.

FIG. 10 is a schematic plan view of the solar cell module of FIG. 9.

FIG. 11 is a schematic rear view of the solar cell module of FIG. 9.

FIG. 12 is a flowchart of a method of manufacturing a solar cell module according to another embodiment of the present inventive concept.

FIGS. 13 through 16 are schematic cross-sectional views sequentially illustrating steps of a method of manufacturing a solar cell module according to an embodiment of the present inventive concept.

### DETAILED DESCRIPTION

The present inventive concept will be described in detail hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this description will be thorough and complete, and will filly convey the scope of the inventive concept to those skilled in the art.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar references in the context of describing the inventive concept (especially in the context of the claims) are to be construed to cover both the singular and the plural, unless otherwise indicated herein or clearly contradicted by context. The terms “comprising,” “having,” “including,” and “containing” are to be construed as open-ended terms, i.e., meaning “including, but not limited to,” unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better describe the inventive concept and is not a limitation on the scope of the inventive concept unless otherwise specified.

The present inventive concept will be described with reference to perspective views, cross-sectional views, and/or plan views in the figures, in which preferred embodiments of the inventive concept are shown. Thus, the profile of an exemplary view may be modified according to manufacturing techniques and/or allowances. That is, the embodiments of the inventive concept are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

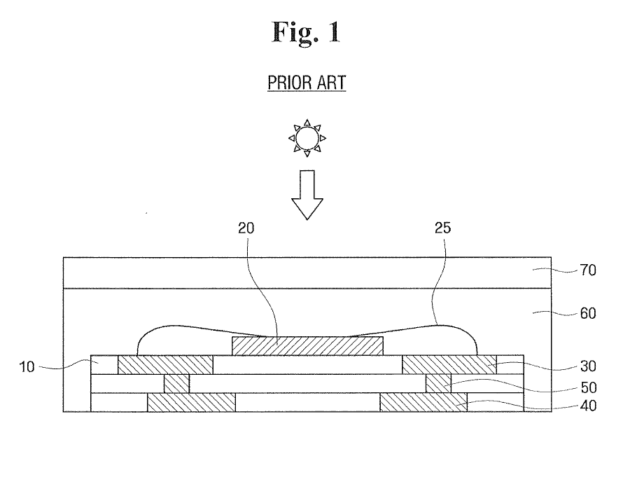

FIG. 1 is a schematic cross-sectional view of a conventional solar cell module. Referring to FIG. 1, a general solar cell module includes a plurality of solar cells 20 disposed on a printed circuit board (PCB) substrate 10, a transparent resin 60 covering and protecting the solar cells 20, and a glass panel 70 that is bonded onto the transparent resin 60 and protects the inside of the solar cell module against external shock.

During operation, light is incident on the solar cell 20. A resulting electric current flows to the PCB substrate 10 through a wire 25 that connects the solar cell 20 to the PCB substrate 10. The PCB substrate 10 can include a first metal layer 30, a conductive via hole 50 and a second metal layer, which are sequentially stacked. The electric current flowing through the wire 25 flows out of the solar cell module for external use through an external contact terminal that is formed with opposite polarities on the second metal layer 40, which is exposed to the outside environment. The wire 25 connects the solar cell 20 to the PCB substrate 10 and may be made of a highly conductive material, such as copper or gold, which facilitate the movement of electrons and holes.

Wire bonding of the solar cell 20 to the PCB substrate 10 requires a space equal to an area occupied by the wire 25. Specifically, when the solar cell 20 is connected to the PCB substrate 10 via the wire 25, the wire 25 projects upward from the solar cell 20. As a result, the wire 25 has to be sufficiently thick to resist erosion against the transparent resin 60. This creates a limitation on how thin the solar cell module can be. That is, with this conventional configuration, it is difficult to achieve a lightweight, ultra-thin solar cell module.

Moreover, as shown in FIG. 1, the configuration in which the external contact terminal is formed on a rear surface of the PCB substrate 10, that is, a surface opposite to the surface where the solar cell 20 is disposed, with the second metal layer 40 acting as the external contact terminal, requires that the first metal layer 30 be separately formed, and that the via hole 50 extending through the PCB substrate 10 be formed to electrically conduct between the first and second metal layers 30 and 40. However, this configuration may make the PCB substrate 10 relatively thick. In addition, since separate steps of forming the second metal layer 40 and the via hole 50 are required, the manufacturing time may be extended.

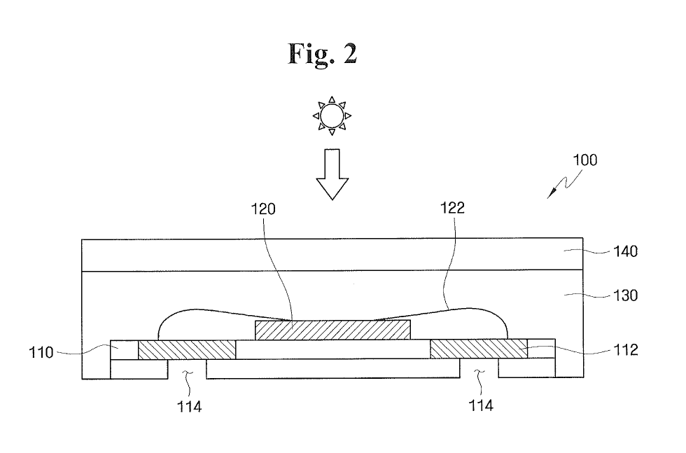

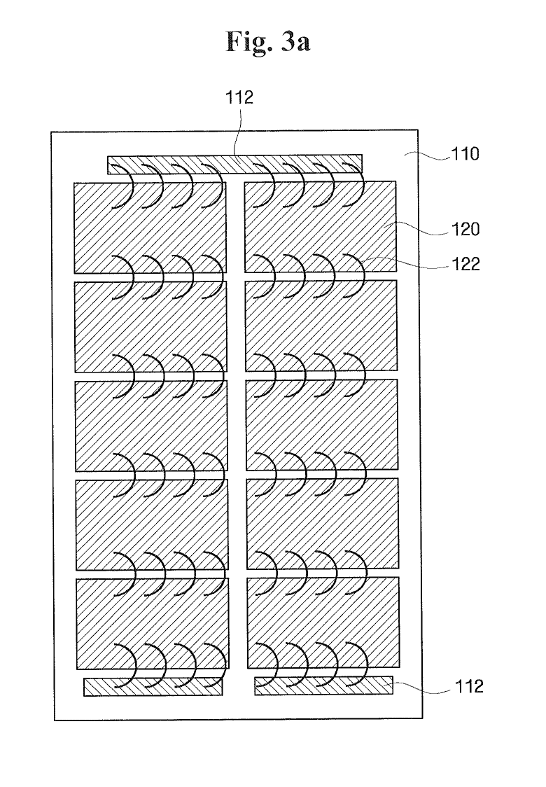

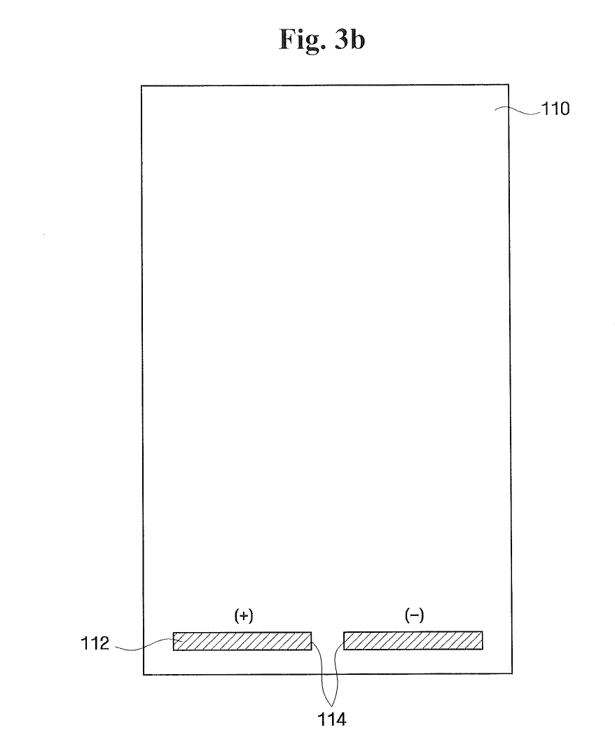

Hereinafter, a solar cell module according to some exemplary embodiments of the present inventive concept will be described in detail with reference to FIGS. 2 through 3B. FIG. 2 is a schematic cross-sectional view of a solar cell module according to an embodiment of the present inventive concept, and FIGS. 3A and 3B are a schematic plan view and a schematic rear view, respectively, of the solar cell module of FIG. 2.

Referring to FIG. 2, the solar cell module 100 according to the present embodiment includes a circuit board 110 and a plurality of solar cells 120 disposed on one surface of the circuit board 110. Metal terminals 112 are formed on one surface of the circuit board 110, and wires 122 are formed to electrically connect the plurality of solar cells 120 and the metal terminals 112. As shown in FIG. 2, the circuit board 110 has a rear surface which includes openings corresponding to the metal terminals 112 to expose the metal terminals 112 to the outside, such that contact terminals 114 are formed.

In some exemplary embodiments, the circuit board 110 is an electrical printed circuit board (PCB) substrate which can be formed by disposing a conductor circuit having good conductivity on an electric insulator material. The circuit board 110 serves to connect and/or mechanically support active or passive electrical circuit elements, acoustic or picture elements, and/or other such elements, such that the elements perform their functions properly. As shown in FIG. 2, in some exemplary embodiments, the plurality of solar cells 120 and the metal terminals 112 are formed on one surface of the circuit board 110. As a result, in these embodiments, the circuit board 110 may serve to insulate these elements from each other while also supporting the elements and bonding the solar cells 120 with the wires 122.

In some exemplary embodiments, the insulating material of the circuit board 110 may include, but is not limited to, polyimide-based resin, phenol-based resin, epoxy-based resin, a transparent material that permits light to pass therethrough, such as glass, transparent plastic film, or transparent plastic sheet. In some particular exemplary embodiments, the transparent plastic film may be or include a polycarbonate-based material, a polysulfone-based material, a polyacrylate-based material, a polystyrene-based material, a polyvinyl chloride (PVC)-based material, a polyvinyl alcohol (PVA)-based material, a polynorbornene-based material, or a polyester-based material.

As illustrated in FIG. 2, in some exemplary embodiments, the metal terminals 112 are formed on one surface of the circuit board 110. While FIG. 2 shows an exemplary embodiment in which the metal terminals 112 are formed on the same layer as the circuit board 110, the inventive concept is not limited to that configuration. For example, in some alternative exemplary embodiments, the metal terminals 112 may be formed to protrude on one surface of the circuit board 110. Furthermore, locations where the metal terminals 112 are formed are not limited to the particular exemplary configuration illustrated in FIG. 2. For example, in a case where the circuit board 110 has a rectangular shape, the metal terminals 112 may be formed at opposing ends of the circuit board 110.

As illustrated in FIG. 2, in some exemplary embodiments, the metal terminals 112 can form the contact terminals 114 that can supply the electrons and holes created by the solar cells 120 to the exterior. In the configuration illustrated in FIG. 2, in some exemplary embodiments, one of the metal terminals 112 forms a first electrode and the other of the metal terminals 112 forms a second electrode, thereby supplying current to the exterior. To facilitate supplying the current to the exterior, the metal terminals 112 are formed of a conductive metal material. Specifically, in some exemplary embodiments, the metal terminals 112 can be made of copper, gold, silver, nickel, or other such materials, or alloys thereof, having high conductivity.

As described above, the circuit board 110 has a rear surface which is opened, that is, includes openings, corresponding to the metal terminals 112 to expose the metal terminals 112 to the exterior, such that the contact terminals 114 are formed.

As describe above, in a conventional solar cell module, a metal layer is typically formed separately on a rear surface of a circuit board 110, and via holes are formed in the circuit board 110 to electrically connect front and rear surfaces of the circuit board 110, thereby forming external contact terminals. With this conventional configuration, however, since metal layers are formed on the front and rear surfaces, respectively, the solar cell module can have an undesirably large overall thickness, since, in that configuration, the PCB layer is required to be undesirable thick. Thus, the material cost of the PCB may increase, and the manufacturing time may be extended due to increased processing steps.

Therefore, in the solar cell module 100 according to exemplary embodiments of the present inventive concept, no separate metal layer is formed on the rear surface of the circuit board 110. According to the exemplary embodiments of the inventive concept, openings (holes) are formed on the front surface of the circuit board 110 to correspond to the metal terminals 112, thus forming the contact terminals 114 so as to externally contact the metal terminals 112. With this configuration, it is not necessary to form a separate metal layer on the rear surface of the circuit board 110. As a result, the overall thickness of the solar cell module 100 is reduced, and the processing time is reduced.

In the solar cell module 100 of the exemplary embodiments illustrated in FIG. 2, the plurality of contact terminals 114 provide a positive electrode and a negative electrode. In embodiments in which the metal terminals 112 and the contact terminals 114 protrude on one surface of the circuit board 110 in forming the openings in the circuit board 110 to form the contact terminals 114, the openings may extend through the circuit board 110 to then be connected to the contact terminals 114.

As described above, in some exemplary embodiments, in a solar cell module 100, a plurality of solar cells 120 are disposed on one surface of the circuit board 110. Light incident on the solar cell 120 creates an electron-hole pair within the semiconductor material. An electric field produced at a PN junction causes electrons to move to an N-type semiconductor and holes to move to a P-type semiconductor, thereby generating electrical current and power. That is, the solar cell 120 includes the semiconductor material that absorbs incident sunlight to generate electric charges and also first and second electrodes disposed on a light-receiving surface of the semiconductor. Depending on the configuration of a system in which the solar cell module 100 is applied, the second electrode may be located on other, e.g., opposite, surfaces.

According to various exemplary embodiments of the inventive concept, the plurality of solar cells 120 may have various shapes and may be disposed on the circuit board 110 in various types, configurations, patterns, spacing, etc., without limitations. In some exemplary embodiments, an adhesive layer is formed on a rear surface of the circuit board 110 such that the respective solar cells 120 can be attached to the circuit board 110.

In general, it is difficult to obtain high efficiency with a single solar cell which has an area larger than a predetermined desirable area. To address this efficiency, in order to increase the electrical power of a solar cell module, a plurality of solar cells 120 may be connected using a connecting electrode, or a grid electrode may be inserted into a unit cell such that electrons are collected efficiently.

In the solar cell module according to the exemplary embodiments of the present inventive concept, a plurality of solar cells may be connected to each other by wires having excellent conductivity. As described above, in some exemplary embodiments, the wires 122 electrically connect the plurality of solar cells 120 disposed on the circuit board 110 to each other and/or electrically connect the plurality of solar cells 120 to the metal terminals 112. Like the metal terminals 112, in some exemplary embodiments, the wires 122 may be made of, for example, copper, gold, silver, nickel, or other such materials or alloys thereof, having high conductivity.

As shown in FIG. 2, a top surface of the circuit board 110 is irradiated with light, e.g., sunlight. In the illustrated configuration, if the wires 122 are formed of an opaque metal material, they would at least partially cover a front surface of the light-receiving surface of the solar cell 120. As a result, an amount of sunlight corresponding to the area of the opaque wire 122 will not be absorbed, thus increasing shading loss. To substantially reduce or eliminate this problem, and therefore reduce the shading loss, the diameter of the wire 122 may be minimized, or the wire 122 may be made of a transparent conductive material that allows light to pass through the wire 122. In some exemplary embodiments, the transparent conductive material of the wire 122 may be or include at least one transparent conductive material such as indium tin oxide (ITO), indium zinc oxide (IZO), carbon nanotube (CNT), nanowire, and conducting polymer. These materials have low resistance and excellent conductivity and optical transmittance (more than 85%). Thus, the transparent wire 122 may be electrically connected to the solar cells 120 so as to carry electrons and holes and deliver and supply power for external use.

Referring, for example, to FIG. 3A, in some exemplary embodiments, when the wire 122 electrically connects the plurality of solar cells 120 disposed on the circuit board 110 to each other, one end of each wire 122 is connected to one surface one of the solar cells 120, and the other end of each wire 122 is connected to one surface of another of the solar cells 120. As described above, the respective solar cells 120 are connected to each other by the wire 122, and the electrons and holes created by the respective solar cells 120 move along the wire 122.

Similarly, in some exemplary embodiments, when the wire 122 electrically connects the plurality of solar cells 120 to the metal terminals 112, one end of a wire 122 is connected to the surface of the outermost solar cell among the plurality of solar cells 120 and the other end of the wire 122 is connected to the metal terminal 112. Therefore, the electrons and holes created by the plurality of solar cells 120 gather in the metal terminals 122 disposed, in some exemplary embodiments, at different ends, forming the contact terminals 114 exposed to the exterior and having different electrodes, that is, a negative (−) electrode and a positive (+) electrode.

Referring again to FIG. 2, in some exemplary embodiments of the present inventive concept, a transparent resin 130 may further be provided on one surface of the circuit board. The transparent resin 130 is filled to one or both surfaces of the circuit board 110 to cover and protect the solar cells 120, the circuit board 110 and the wires 122 connecting the solar cells 120.

In some exemplary embodiments, the transparent resin 130 is coated on the circuit board 110 in part or entirely, and surrounds the plurality of solar cells 120, one or both surfaces of the circuit board 110 and the wires 122 connecting the solar cells 120 and the circuit board 110. Since the transparent resin 130 allows the penetration of light, the efficiency of the solar cell 120 is not negatively affected by the transparent resin 130, even if the top surface of the light-receiving region of the solar cell 120 is filled with the transparent resin 130.

Since the transparent resin 130 is selectively coated on only a required region of the circuit board 110, the amount of transparent resin 130 and, therefore, the overall weight of the solar cell module, can be reduced. In some exemplary embodiments, the transparent resin 130 may be formed of any transparent material that allows the penetration of light. IN some exemplary embodiments, the transparent resin 130 may be, for example, underfill resin or ethylene vinyl acetate (EVA).

According to some exemplary embodiments, in a configuration in which the transparent resin 130 is coated on the rear surface of the circuit board 110, the rear surface of the circuit board 110 can be advantageously protected. However, in such a configuration, the electrons and holes formed by the solar cells 120 are not allowed to contact the contact terminals 114. Thus, in such a configuration, in some exemplary embodiments, holes may be formed in the transparent resin 130 to allow an external device to contact the metal terminals 112 through the contact terminals 114, thereby supplying power generated from the solar cells 120 to the external device.

In some exemplary embodiments, a transparent panel 140 is disposed on the transparent resin 130. Since in some embodiments the transparent resin 130 may not be rigid enough to protect the internal components against external shock, the transparent panel 140 is provided on the cured transparent resin 130 to provide additional protection for the internal components, including the solar cells 120, the circuit board 110 and the wire 122, against external shock.

As illustrated in FIG. 2, in some exemplary embodiments, since the transparent panel 140 is positioned at a top end of the light-receiving surface of the solar cell 120, it is preferably formed of a transparent material that permits light to pass through. In addition, in some exemplary embodiments, the transparent panel 140 may be formed of a material having a relatively high hardness such that the solar cells 120 are supported and protected. For example, in some particular exemplary embodiments, the transparent panel 140 may include or be made of glass having high hardness or tempered glass.

The layout of the solar cells 120 and the pattern diagram of the wires 122 according to particular exemplary embodiments of the present inventive concept are shown in FIGS. 3A and 3B. FIG. 3A is a schematic rear view of the solar cell module of FIG. 2, and FIG. 3B is a schematic plan view of the solar cell module of FIG. 2.

As described above, the solar cell module 100 according to the exemplary embodiments of the present inventive concept includes the plurality of solar cells 120 disposed on the circuit board 110. In accordance with the inventive concept, the solar cells 120 may have various shapes and configurations and may be disposed in various patterns and configurations. In some particular exemplary embodiments, in order to maximize the spatial efficiency of arranging the plurality of solar cells 120, the solar cells 120 may be arranged parallel to each other at the smallest possible distance apart. In the illustrated exemplary embodiments, the plurality of solar cells 120 are depicted as being rectangular in shape. However, the present inventive concept is not limited to that configuration, and may have other various shapes.

According to the particular illustrated exemplary embodiments, the plurality of solar cells 120 are connected to each other by the wires 122, and the metal terminals 112 are formed at opposing ends of each of the solar cell 120. The metal terminals 112 are electrically connected to the respective solar cells 120 by the wires 122, providing the contact terminals 114 that allow external contacts. In a particular configuration of some exemplary embodiments, as shown in FIG. 3A, if the plurality of solar cells 120 are vertically arranged in parallel to each other, the metal terminals 112 may be horizontally disposed to connect the solar cell 120 of the left column to the solar cell 120 of the right column. In the illustrated exemplary embodiment, since the metal terminal 112 extends horizontally, the solar cells 120 disposed in the left and right columns are all connected.

In FIG. 3A, the lower metal terminals 112 are separated from each other to form different electrodes. In the illustrated exemplary embodiment, the lower metal terminals 112 are separated from each other, forming a negative (−) electrode in the left column and a positive (+) electrode in the right column.

As shown in FIG. 3B, openings are formed on rear surfaces of the metal terminals 112, forming the contact terminals 114, so that the rear surfaces of the metal terminals 112 are exposed to the exterior. Therefore, the power generated from the solar cell module 100 according to the embodiment of the present inventive concept can be externally supplied through the contact terminals 114.

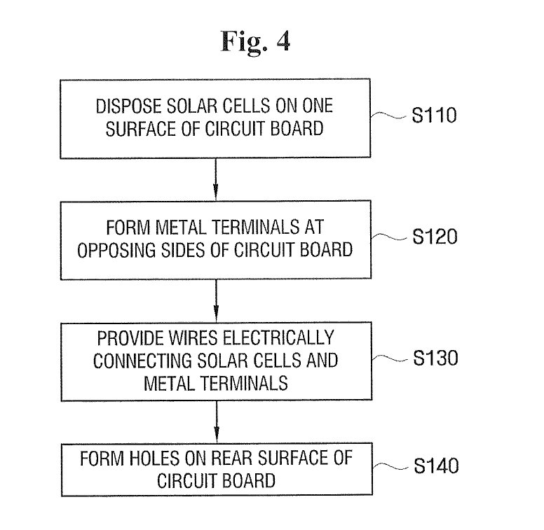

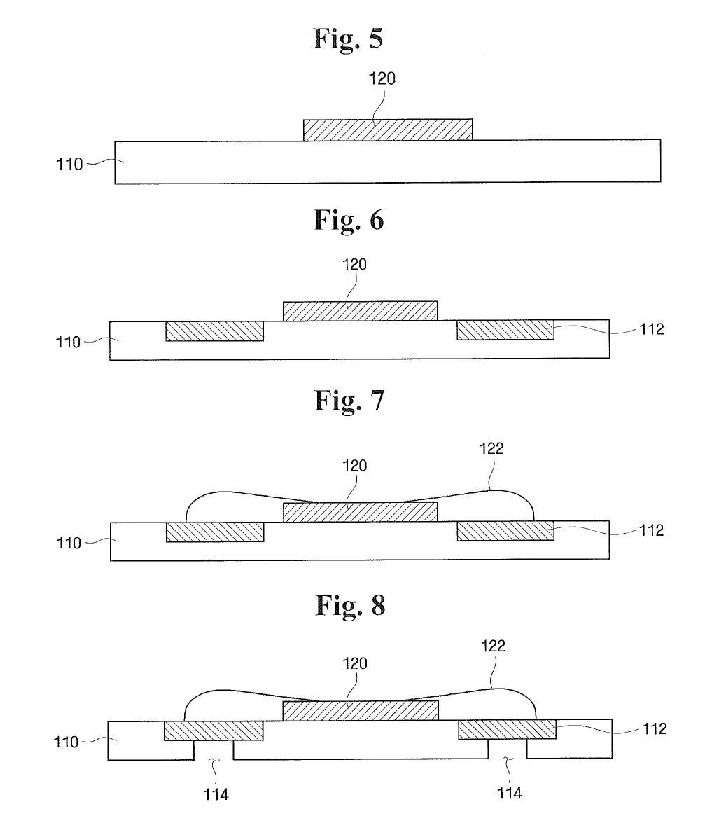

A method of manufacturing a solar cell module according to exemplary embodiments of the present inventive concept will be described with reference to FIGS. 4 through 8. FIG. 4 is a flowchart of a method of manufacturing a solar cell module according to exemplary embodiments of the present inventive concept, and FIGS. 5 through 8 are schematic cross-sectional views sequentially illustrating steps of a method of manufacturing a solar cell module according to exemplary embodiments of the present inventive concept.

Referring to FIG. 4, the method of manufacturing a solar cell module according to some exemplary embodiments of the present inventive concept includes disposing a plurality of solar cells on one surface of a circuit board (Step S110), forming metal terminals on the circuit board (Step S120), providing wires electrically connecting the plurality of solar cells and the metal terminals (Step S130), and forming holes on a rear surface of the circuit board at locations corresponding to the metal terminals, and forming contact terminals (Step S140).

According to the method of the exemplary embodiments, a circuit board 110 is provided, and a plurality of solar cells 120 are disposed on the circuit board 110 (Step S110). In the exemplary embodiment shown in FIG. 5, the circuit board 110 is configured to have front and rear planar surfaces. Alternatively, in some exemplary embodiments, grooves in which metal terminals 112 are to be formed, and/or openings forming contact terminals 114, may be pre-fabricated on the circuit board 110.

As described above, in some exemplary embodiments, the material of the circuit board 110 may be or include, for example, polyimide-based resin, phenol-based resin, epoxy-based resin, a transparent material that permits light to pass therethrough, such as glass, transparent plastic film, or transparent plastic sheet.

In the plurality of solar cells 120, the incident light creates an electron-hole pair within a semiconductor material, and an electric field produced at a PN junction causes electrons to move to an N-type semiconductor and holes to move to a P-type semiconductor, thereby generating electrical current and power. Each of the solar cells 120 may include a semiconductor material that absorbs incident light, e.g., sunlight, and generates electric charges from the incident light, and first and second electrodes disposed on a light-receiving surface of the semiconductor material.

Next, metal terminals 112 are formed at one surface of the circuit board 110 (Step S120). As shown in FIG. 6, in some exemplary embodiments, the metal terminals 112 may be buried on the circuit board 110, so that top surfaces of the metal terminals 112 are at the same height as the front surface of the circuit board 110. Alternatively, in some exemplary embodiments, the metal terminals 112 may be formed on the front surface of the circuit board 110, so that they protrude above the front surface of the circuit board 110 a distance substantially equal to their heights. The metal terminals 112 may be formed of a conductive metal material. For example, in some exemplary embodiments, the metal terminals 112 may be made of copper, gold, silver, nickel, or alloys thereof, having high conductivity.

In accordance with exemplary embodiments of the inventive concept, the locations at which the metal terminals 112 are formed are not limited, and in a case where the circuit board 110 has a rectangular shape, the metal terminals 112 may be formed, for example, at opposing ends of the circuit board 110. The metal terminals 112 form the contact terminals 114 that can supply the electrons and holes generated by the solar cells 120 to the exterior. In this configuration, one of the metal terminals 112 forms a first electrode and the other of the metal terminals 112 forms a second electrode, thereby supplying current to the exterior.

Referring to FIG. 7, next, wires 122 electrically connecting the plurality of solar cells 122 and the metal terminals 112 are provided (Step S130). In some exemplary embodiments, the wires 122 may be made of, for example, copper, nickel, gold or silver. The wires 122 may be provided between the plurality of solar cells 120 to electrically connect the plurality of solar cells 120 to each other before or after the wires 122 connecting the solar cells 120 to the metal terminals 112 are provided. Alternatively, in some exemplary embodiments, the wires 122 connecting the plurality of solar cells 122 may be provided simultaneously with the wires 122 connecting the solar cells 120 to the metal terminals 112.

If a wire 122 covers a front surface of the solar cell 120, an amount of sunlight corresponding to the area of the wire 122 will not be absorbed, thus increasing shading loss. Thus, a diameter of the wire 122 may be minimized, or the wire 122 may be made of a transparent conductive material that allows light to pass through the wire 122.

Referring to FIG. 8, next, holes are formed on the rear surface of the circuit board 110 and the contact terminals, through which the metal terminals 112 are exposed to the exterior, are formed (Step S140). As described above, the holes for forming the contact terminals 114 may be pre-fabricated in the circuit board 110.

As noted above, in the conventional solar cell module, a metal layer is separately formed on a rear surface of a circuit board 110 and via holes are formed in the circuit board 110 to electrically conduct front and rear surfaces of the circuit board 110, thereby forming external contact terminals. With this conventional configuration, however, since metal layers are formed on the front and rear surfaces, respectively, the overall thickness of the solar cell module may be relatively thick due to the required thickness of the PCB layer. Thus, the material cost of the PCB may increase and the manufacturing time may be extended due to increased processing steps.

Therefore, in contrast to the conventional solar cell module, in the method of manufacturing the solar cell module 100 according to the exemplary embodiments of the present inventive concept, a metal layer is not separately formed on the rear surface of the circuit board 110, and openings are formed on the front surface of the circuit board 110 to correspond to the metal terminals 112, thus forming the contact terminals 114 so as to externally contact the metal terminals 112. With this configuration, it is not necessary to form a separate metal layer on the rear surface of the circuit board 110. Therefore, the overall thickness of the solar cell module 100 and the processing time are reduced.

Next, in some exemplary embodiments, the transparent resin 130 surrounding the plurality of solar cells 120 may further be provided. According to the exemplary embodiments, the transparent resin 130 may be, for example, underfill resin or ethylene vinyl acetate (EVA). The transparent resin 130 is filled to one or both surfaces of the circuit board 110 to cover and protect the solar cells 120, the circuit board 110 and the wires 122 connecting the solar cells 120.The transparent resin 130 is coated on the circuit board 110 in part or entirely, and surrounds the plurality of solar cells 120, one or both surfaces of the circuit board 110 and the wires 122 connecting the solar cells 120 and the circuit board 110. Since the transparent resin 130 allows the penetration of light, the efficiency of the solar cell 120 is not negatively affected by the transparent resin 130, even if the top surface of the light-receiving region of the solar cell 120 is filled with the transparent resin 130.

Next, in some exemplary embodiments, the method of manufacturing the solar cell module 100 according to the embodiment of the present inventive concept may further include disposing a transparent panel 140 on the transparent resin 130. Since the transparent resin 130 may not be rigid enough to protect the internal components against external shock, the transparent panel 140 may be disposed on the cured transparent resin 130 to provide additional protection for the internal components, including the solar cells 120, the circuit board 110 and the wire 122, against external shock.

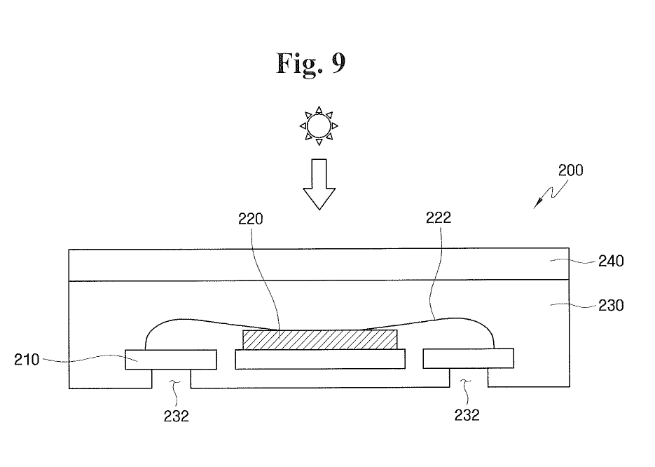

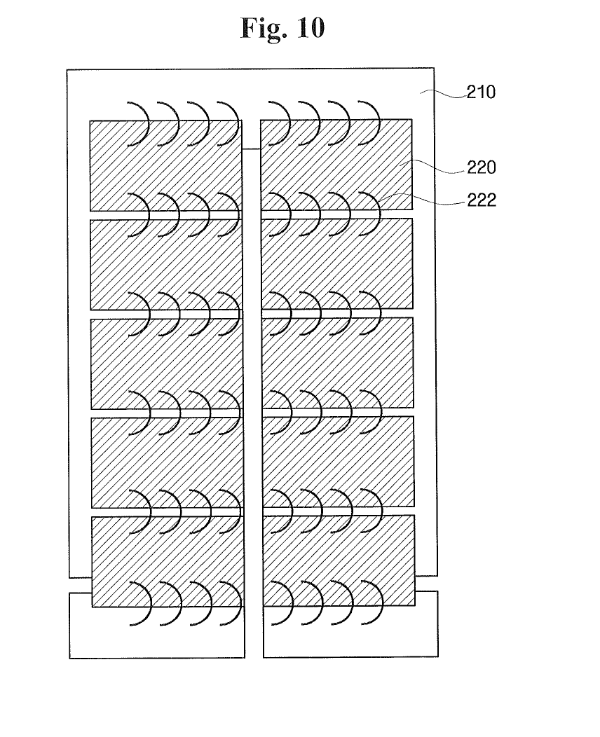

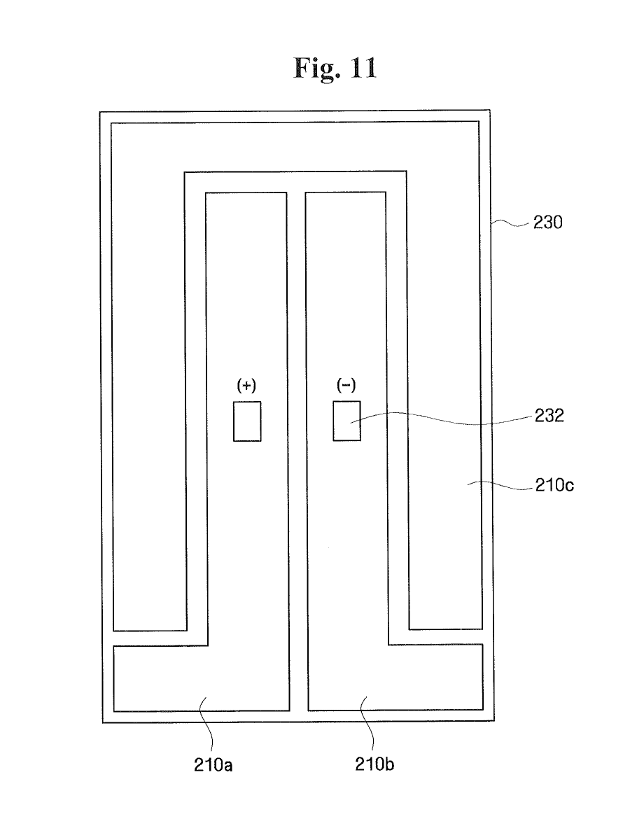

Hereinafter, a solar cell module 200 according to other exemplary embodiments of the present inventive concept will be described with reference to FIGS. 9 through 11. FIG. 9 is a schematic cross-sectional view of a solar cell module 200 according to other exemplary embodiments of the present inventive concept, FIG. 10 is a schematic plan view of the solar cell module of FIG. 9, and FIG. 11 is a schematic rear view of the solar cell module of FIG. 9.

The solar cell module 200 according to the present exemplary embodiments includes a metal circuit board 210, a plurality of solar cells 220 disposed on one surface of the metal circuit board 210, wires 222 electrically connecting the plurality of solar cells 220 and the metal circuit board 210, and a transparent resin 230 surrounding both surfaces of the metal circuit board 210. In some exemplary embodiments, the transparent resin 230 is formed with holes to expose portions of the metal circuit board 210 to the outside, forming contact terminals 232.

The solar cell module 200 according to the present exemplary embodiments of the present inventive concept includes the metal circuit board 210, instead of the circuit board 110 of the previous embodiment. The metal circuit board 210 of the present embodiments supports the plurality of solar cells 220 stacked thereon, and also functions as contact terminals 232 exposed to the exterior, without the requirement for separately provided metal terminals. Since the metal circuit board 210 is made of a conductive metal material, separate metal terminals for carrying electrons and holes generated by the solar cells 220 are not required.

In some exemplary embodiments, the metal circuit board 210 may be made of any conductive metal. In addition, in accordance with the inventive concept, the metal circuit board 210 may have various shapes without limitations. For example, the metal circuit board 210 may be configured such that it is divided into a plurality of regions, as shown in FIG. 11. In the illustrated exemplary embodiment, the metal circuit board 210 may include first and second regions 210a and 210b extending lengthwise in parallel to each other, and a third region 210c surrounding the first and second regions 210a and 210b. In accordance with various exemplary embodiments of the inventive concept, the metal circuit board 210 may be divided into a plurality of regions having various shapes to support the solar cells 220 while having separate ends to form different electrodes (that is, positive and negative electrodes). In the illustrated exemplary embodiments, the first region 210a of the metal circuit board 210 forms a positive (+) electrode, the second region 210b forms a negative (−) electrode, and the third region 210c connects solar cells 220 of left and right columns vertically disposed in parallel.

In some exemplary embodiments, the other elements, for example, the solar cells 220, the wires 222 connecting the solar cells 220 to each other, and the transparent resin 230, are the same as those described in detail above in connection with the previous embodiments of the present inventive concept. Accordingly, detailed description of these elements will not be repeated. In the current exemplary embodiments of the present inventive concept, however, the metal circuit board 210 itself has conductivity without separate metal terminals. Thus, in order to protect the metal circuit board 210 so as not to be exposed to the external environment at regions other than the contact terminals 232, in some exemplary embodiments, the transparent resin 230 is formed on both front and rear surfaces of the metal circuit board 210. That is, the transparent resin 230 is provided so as to allow the metal circuit board 210 and the plurality of solar cells 220 to be entirely buried in the transparent resin 230, thereby covering and protecting the metal circuit board 210 and the solar cells 220 against external shock.

Since the transparent resin 230 is formed on the rear surface of the metal circuit board 210, holes are formed at portions of the rear surface of the metal circuit board 210 to extend through the transparent resin 230 to allow the metal circuit board 210 to be exposed to the exterior, forming the contact terminals 232. As in the previously described exemplary embodiments, the transparent resin 230 may be, for example, underfill resin or ethylene vinyl acetate (EVA).

A transparent panel 240 may further be disposed on the transparent resin 230 to reinforce the transparent resin 230 and protect the internal components.

In the solar cell module 200 according to the current exemplary embodiments, the circuit board and the metal terminals formed on one surface of the circuit board are replaced by a single component, that is, the metal circuit board 210, thereby reducing the overall thickness of the solar cell module 200 while shortening the processing time.

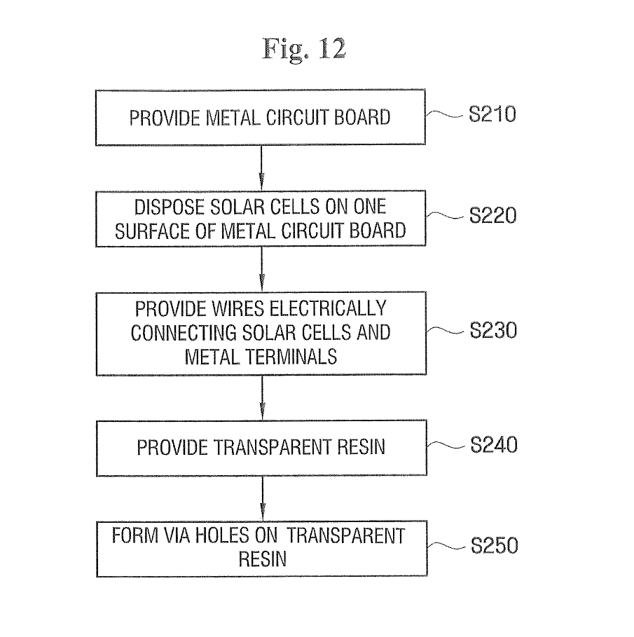

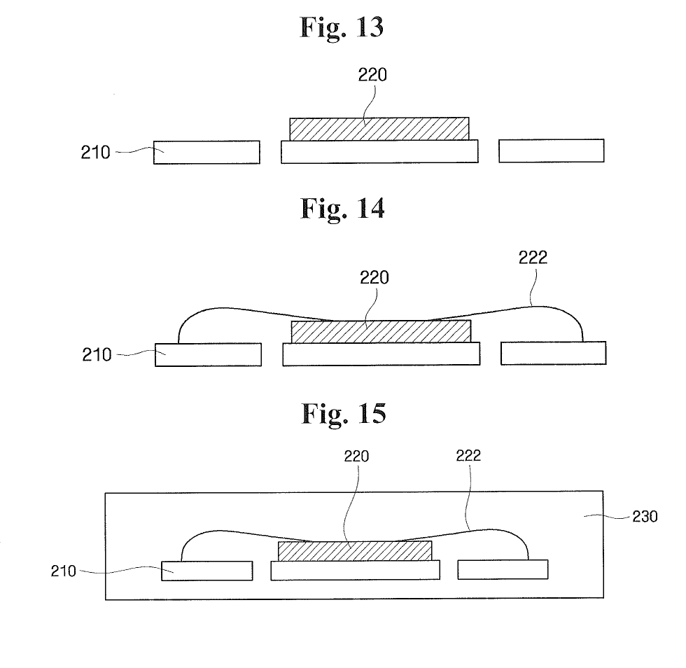

Next, a method of manufacturing a solar cell module according to other embodiments of the present inventive concept will be described with reference to FIGS. 12 through 16. FIG. 12 is a flowchart of a method of manufacturing a solar cell module according to other embodiments of the present inventive concept, and FIGS. 13 through 16 are schematic cross-sectional views sequentially illustrating steps of a method of manufacturing a solar cell module according to an embodiment of the present inventive concept.

The method of manufacturing a solar cell module according to the embodiments of the present inventive concept includes providing a metal circuit board (Step S210), disposing a plurality of solar cells on one surface of the metal circuit board (Step S220), providing wires electrically connecting the plurality of solar cells and the metal circuit board (Step S230), providing a transparent resin surrounding both surfaces of the metal circuit board (Step S240), and forming via holes in the transparent resin to expose portions of the metal circuit board, and forming contact terminals (Step S250).

Referring to FIG. 13, in some exemplary embodiments, first, a metal circuit board 210 is provided (Step S210). As described above, the metal circuit board 210 may be divided into a plurality of regions. That is, the metal circuit board 210 having a plurality of prefabricated regions may be provided. Alternatively, the metal circuit board 210 is provided in its entirety and is divided into a plurality of regions. The dividing of the metal circuit board 210 may include forming first and second regions extending lengthwise in parallel to each other, and forming a third region surrounding the first and second regions. As described above, the providing of the metal circuit board 210 is not limited to the illustrated example, and the metal circuit board 210 may be divided in various manners to form different electrodes.

Next, the plurality of solar cells 220 are disposed on one surface of the metal circuit board 210 (Step S220). In a case in which the metal circuit board 210 has a plurality of divided regions, the plurality of solar cells 220 may be disposed such that they are all connected to each other by the metal circuit board 210 having the divided regions.

Referring to FIG. 14, in some exemplary embodiments, next, wires 222 electrically connecting the plurality of solar cells 220 and the metal circuit board 210 are provided (Step S230). In some exemplary embodiments, the providing of the wires 222 may include providing the wires 222 between the plurality of solar cells 220 to electrically connect the solar cells to each other. In some exemplary embodiments, the wires 222 may be made of for example, copper, gold, silver, nickel, or alloys thereof. Alternatively, in some exemplary embodiments, the wires 222 may also be made of a transparent conductive material.

Referring to FIG. 15, in some exemplary embodiments, next, a transparent resin 230 surrounding both surfaces of the metal circuit board 210 may be provided (Step S240). In some exemplary embodiments, the transparent resin 230 may be, for example, underfill resin or ethylene vinyl acetate (EVA). As described above, in some exemplary embodiments, a transparent panel 240 may further be disposed on the transparent resin 230 to protect the metal circuit board 210 and the solar cells 220. In addition, the transparent resin 230 may be provided so as to allow the metal circuit board 210 and the plurality of solar cells 220 to be entirely buried in the transparent resin 230, thereby covering and protecting the metal circuit board 210 and the solar cells 220 against external shock.

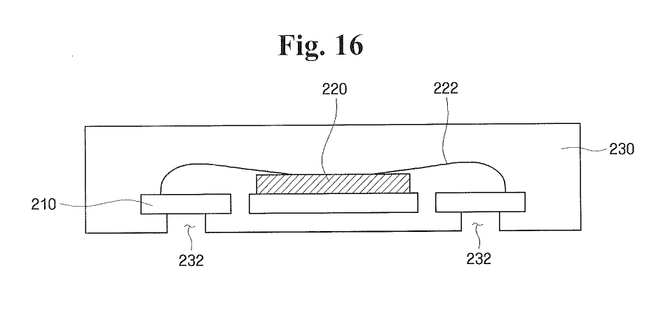

Referring to FIG. 16, in some exemplary embodiments, next, holes are formed in the transparent resin 230 to expose portions of the metal circuit board 210, and forming contact terminals 232 (Step S250). Accordingly, the power provided from the solar cells 220 can be supplied to the exterior through contacts with the contact terminals 232.

In the solar cell module 200 according to the current embodiments, the circuit board and the metal terminals formed on one surface of the circuit board are replaced by a single component, that is, the metal circuit board 210, thereby reducing the overall thickness of the solar cell module 200 while shortening the processing time.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A solar cell module, comprising:
a circuit board;
a plurality of solar cells disposed on a first surface of the circuit board;
a plurality of metal terminals formed on the first surface of the circuit board; and
a plurality of wires electrically connecting the plurality of solar cells and the metal terminals,
wherein the circuit board has a second surface opposite to the first surface, the rear surface comprising openings corresponding to the metal terminals, the openings exposing the metal terminals to an exterior of the solar cell module, thus forming contact terminals for the solar cell module.

2. The solar cell module of claim 1, wherein the wires comprise at least one of copper, nickel, gold and silver.

3. The solar cell module of claim 1, wherein the plurality of solar cells are connected to each other by the wires.

4. The solar cell module of claim 1, wherein an adhesive layer is interposed between the plurality of solar cells and the circuit board.

5. The solar cell module of claim 1, further comprising a transparent resin at least partially surrounding the plurality of solar cells.

6. The solar cell module of claim 5, wherein the transparent resin comprises at least one of underfill resin and ethylene vinyl acetate (EVA).

7. The solar cell module of claim 1, further comprising a transparent panel disposed on the transparent resin.

8. The solar cell module of claim 1, wherein the metal terminals are formed at opposite ends of the circuit board.

9. A solar circuit module, comprising:
a metal circuit board;
a plurality of solar cells disposed on a first surface of the metal circuit board;
a plurality of wires electrically connecting the plurality of solar cells and the metal circuit board; and
a transparent resin at least partially surrounding the first surface of the metal circuit board and a second surface of the metal circuit board opposite the first surface of the metal circuit board,
wherein the transparent resin comprises a plurality of holes exposing portions of the metal circuit board to an exterior of the solar circuit module, thus forming contact terminals for the solar circuit module.

10. The solar circuit module of claim 9, wherein the metal circuit board is divided into a plurality of regions.

11. The solar circuit module of claim 9, wherein the metal circuit board comprises first and second regions extending lengthwise in parallel, and a third region at least partially surrounding the first and second regions.

12. The solar circuit module of claim 9, wherein the plurality of solar cells are connected to each other by the wires.

13. The solar circuit module of claim 9, wherein the wires comprise at least one of copper, nickel, gold and silver.

14. The solar circuit module of claim 9, wherein the transparent resin comprises at least one of underfill resin and ethylene vinyl acetate (EVA).

15. The solar circuit module of claim 9, further comprising a transparent panel disposed on the transparent resin.

16. An energy conversion module, comprising:
a substrate, the substrate having a first surface and a second surface opposing the first surface;
a plurality of solar cells disposed on the first surface of the substrate;
a plurality of metal terminals formed on the first surface of the substrate; and
a plurality of wires formed to electrically connect the plurality of solar cells and the metal terminals;
a transparent resin at least partially surrounding the solar cells; and
a transparent panel disposed on the transparent resin; wherein
the second surface of the substrate comprises a plurality of openings in correspondence with the metal terminals to expose the metal terminals to an exterior of the energy conversion module, thus forming contact terminals of the energy conversion module.

17. The energy conversion module of claim 16, wherein the substrate is a circuit board.

18. The energy conversion module of claim 17, further comprising an adhesive layer between the plurality of solar cells and the circuit board.

19. The energy conversion module of claim 16, wherein the energy conversion module is a solar cell module which converts light energy to electrical energy.

20. The energy conversion module of claim 16, wherein the wires comprise at least one of copper, nickel, gold and silver.
